(19) United States
(12) Patent Application Publication
(10) Pub. No.: US 2010/0109025 A1
(43) Pub. Date: May 6, 2010

(54) OVER THE MOLD PHOSPHOR LENS FOR AN LED

(75) Inventor: Jerome C. Bhat, San Francisco, CA (US)

Correspondence Address: PHILIPS INTELLECTUAL PROPERTY & STANDARDS, P.O. BOX 3001, BRIARCLIFF MANOR, NY, 10510, US

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/265,050

(22) Filed: Nov. 5, 2008

(51) Int. Cl. H01L 21/50; H01L 33/00

(52) U.S. Cl. 257/88; 438/27; 257/E21.499; 257/E33.056

(57) ABSTRACT

Rectangular LED dice are mounted on a submount wafer. A first mold has rectangular indentations in it generally corresponding to the positions of the LED dice on the submount wafer. The indentations are filled with silicone, which when cured forms a clear first lens over each LED. Since the wafer is precisely aligned with the mold, the top surfaces of the first lenses are all within a single reference plane irrespective of any x, y, and z misalignments of the LEDs on the wafer. A second mold has rectangular indentations filled with a phosphor-infused silicone so as to form a precisely defined phosphor layer over the clear first lens, whose inner and outer surfaces are completely independent of any misalignments of the LEDs. A third mold forms an outer silicone lens. The resulting PC-LEDs have high chromaticity uniformity from PC-LED to PC LED within a submount wafer and from wafer to wafer, and high color uniformity over a wide viewing angle.

### FIELD OF THE INVENTION

This invention relates to light emitting diodes (LEDs) and, in particular, to a technique for forming a phosphor-converted LED (PC-LED).

### BACKGROUND

It is known to form a silicone lens over an LED where the lens is infused with a phosphor powder. For example, the LED die may emit blue light, and the phosphor may emit yellow-green light (e.g., a YAG phosphor), or the phosphor may be a combination of red and green phosphors. The combination of the blue light leaking through the lens and the light emitted by the phosphor generates white light. Many other colors may be generated in this way by using the appropriate phosphors. However, such phosphor-converted LEDs (PC-LEDs) do not have a reproducible color from LED to LED over all viewing angles due to one or more of the following reasons: variations in the thickness of the phosphor coating, the phosphor being at different average distances from the LED die at different viewing angles, optical effects, misalignments and variations in LED die positioning with respect to the lens, and other factors. U.S. Pat. No. 7,322,902, assigned to the present assignee and incorporated herein by reference, describes a molding process for forming silicone lenses over LEDs. That patent describes a molding process for forming a hemispherical phosphor-infused lens over a hemispherical clear lens. However, that embodiment still does not produce a PC-LED having very consistent color vs. viewing angle.

Consistent color vs. viewing angle is extremely important where the light is not mixed and diffused, such as in a projector, a flashlight, automobile lights, or a camera flash where the light sources are directly magnified and projected onto a surface. Consistent color vs. viewing angle is also extremely important when multiple PC-LEDs are used together and need to be matched to create a uniform color across a screen.

Therefore, what is needed is a PC-LED that has very highly controlled color vs. viewing angle.

### SUMMARY

A technique for forming multiple lenses, including a phosphor-infused lens, for a PC-LED is described where the characteristics and effects of the phosphor lens are more carefully controlled than in U.S. Pat. No. 7,322,902.

LED dice (e.g., GaN LEDs that emit visible blue light) are mounted on a submount wafer in an array. There may be hundreds of LED dice mounted on the wafer. The submount wafer may be a ceramic substrate, a silicon substrate, or other type of support structure with the LED dice electrically connected to metal pads on the support structure.

A first mold has first indentations in it corresponding to the ideal positions of the LED dice on the submount wafer. The indentations are filled with liquid or softened silicone. The submount wafer is precisely aligned with respect to the first mold so that the LEDs are immersed in the silicone. The silicone is then cured to form a hardened lens material. The indentations are substantially rectangular, with a planar surface, so a first clear lens is formed over each of the LEDs having a rectangular shape generally proportional to the LED shape. The depth and widths of the indentations are large enough so that the lens will cover the LEDs under worst case misalignments of the LEDs on the submount wafer in the x, y, and z directions. Misalignment in the z direction is caused by variations in the submount wafer surface and variations in the thicknesses of the metal bonds between the LEDs and the submount wafer. Since the submount wafer is precisely aligned to the mold, the “top” surface of the flat lenses will all be within a single reference plane.

A second mold has larger indentations that are precisely aligned to the first indentations in the first mold. The second indentations have a substantially rectangular shape proportional to the shapes of the LEDs and first indentations. The second indentations are filled with a liquid or softened mixture of silicone and phosphor. The submount wafer is then precisely aligned with respect to the second mold so that the LEDs and first lenses are immersed in the silicone/phosphor. The silicone is then cured to form a hardened second lens material.

Since the top surfaces of the first lenses were all in the same reference plane, and the first and second indentations are precisely aligned with each other, the inner and outer surfaces of the second lens (containing the phosphor) are completely determined by the molds rather than any x, y, z misalignments of the LEDs. Therefore, the thickness of the second lens (containing the phosphor) is predicable and precisely the same for all the LEDs on the submount wafer, and all lenses are formed concurrently. Further, the phosphor layer is substantially uniformly illuminated by the blue LED so that blue light uniformly leaks through the phosphor lens layer. Therefore, the resulting color (or chromaticity) of the PC-LED will be reproducible from LED to LED and uniform across a wide range of viewing angles.

A third substantially rectangular lens is then molded over the phosphor-infused second lens, which may be harder than the other lenses and have a lower index of refraction.

The submount wafer is then diced to separated out the individual PC-LEDs. The submount/PC-LED may then be mounted on a circuit board or packaged.

The inventive technique applies equally to PC-LEDs where most or virtually all LED light (e.g., blue or UV) is absorbed by the phosphor layer, and the resulting light is primarily the light emitted by the phosphor layer. Such PC-LEDs would use a high density of phosphor particles in the phosphor lens layer.

### BRIEF DESCRIPTION OF THE DRAWINGS

FIG. 1 is a side view of four LED dice mounted on a submount wafer, where the LED dice are shown inadvertently mounted at different heights and/or slightly misaligned.

FIG. 2 is a side view of the LED dice being inserted into indentations in a first mold filled (or partially filled) with a liquid (or softened) inner lens material for forming a planarized first clear lens.

FIG. 3 is a side view of the LED dice submerged in the liquid lens material and the lens material being cured.

FIG. 4 is a side view of the LED dice, after removal from the first mold, being inserted into indentations in a second mold filled (or partially filled) with a liquid (or softened) lens material containing phosphor powder, where the first clear lens causes the resulting phosphor filled lens to have precise inner and outer dimensions.

FIG. 5 is a side view of the LED dice, after removal from the second mold, being inserted into indentations in a third mold filled (or partially filled) with a liquid (or softened) outer lens material.

FIG. 6 is a side view of the LED dice submerged in the outer lens material while curing the outer lens material.

FIG. 7 is a side view of the LED dice with the three molded lenses.

FIG. 8 is a front view of the submount wafer populated with an array of the LED dice with the three molded lenses.

FIG. 9 is a cross-sectional view of a single flip chip LED/submount separated from the submount wafer and mounted on a circuit board.

Elements labeled with the same numerals are the same or equivalent.

### DETAILED DESCRIPTION

As a preliminary matter, a conventional LED is formed on a growth substrate. In the example used, the LED is a GaN-based LED, such as an AlInGaN LED, for producing blue or UV light. Typically, a relatively thick n-type GaN layer is grown on a sapphire growth substrate using conventional techniques. The relatively thick GaN layer typically includes a low temperature nucleation layer and one or more additional layers so as to provide a low-defect lattice structure for the n-type cladding layer and active layer. One or more n-type cladding layers are then formed over the thick n-type layer, followed by an active layer, one or more p-type cladding layers, and a p-type contact layer (for metallization).

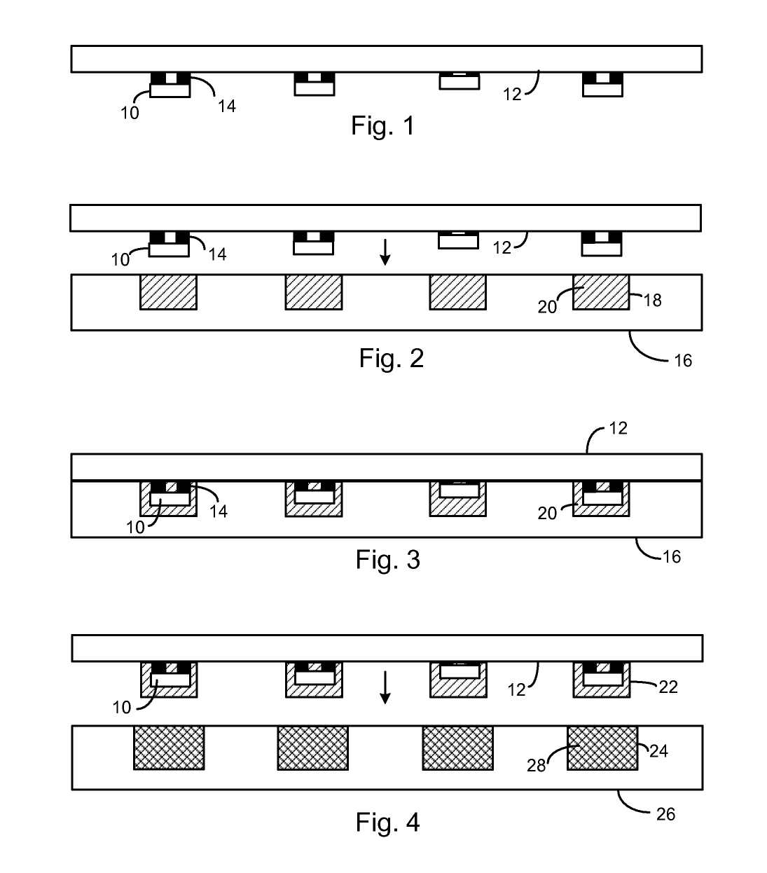

Various techniques are used to gain electrical access to the n-layers. In a flip-chip example, portions of the p-layers and active layer are etched away to expose an n-layer for metallization. In this way the p contact and n contact are on the same side of the chip and can be directly electrically attached to the submount contact pads. Current from the n-metal contact initially flows laterally through the n-layer. In contrast, in a vertical injection (non-flip-chip) LED, an n-contact is formed on one side of the chip, and a p-contact is formed on the other side of the chip. Electrical contact to one of the p or n-contacts is typically made with a wire or a metal bridge, and the other contact is directly bonded to a package (or submount) contact pad. A flip-chip LED is used in the examples of FIGS. 1-9 for simplicity.

Examples of forming LEDs are described in U.S. Pat. Nos. 6,649,440 and 6,274,399, both assigned to Philips Lumileds Lighting, LLC and incorporated by reference.

FIG. 1 is a side view of four LED dice 10 mounted on a submount wafer 12. The submount wafer 12 is typically ceramic or silicon, with metal leads for connection to a printed circuit board, a package leadframe, or any other structure. The substrate wafer 12 may be circular or rectangular. Prior to mounting on the submount wafer 12, the LED dice 10 are separated from other LEDs grown on the growth substrate (e.g., sapphire) by a standard sawing or scribing-breaking operation and positioned on the submount wafer 12 by an automatic placement machine. The metal pads on the LED dice 10 are bonded to corresponding gold bumps on the submount wafer 12 by ultrasonic bonding. The combined metal pads and gold bumps are shown as metal bonds 14. The gold bumps are connected, by conductive vias through the submount wafer 12, to bonding pads on the bottom surface of the submount wafer 12 for surface mounting to a circuit board. Any configuration of metal may be used on the submount wafer 12 for providing terminals to connection to a power supply. In the preferred embodiment, the growth substrate is removed from the flip-chip LEDs after mounting on the wafer 12.

There is some misalignment of the LED dice 10 on the submount wafer 12 due to tolerances, and the heights of the LED dice 10 above the wafer 12 surface vary somewhat due to the tolerances of the metal pads, gold bumps, and ultrasonic bonding. Such non-uniformity is shown in FIG. 1.

In FIG. 2, a first mold 16 has indentations 18 corresponding to the desired shape of a first lens over each LED die 10. The mold 16 is preferably formed of a metal. A very thin non-stick film (not shown), having the general shape of mold 16, may be placed over the mold 16 to prevent the sticking of silicone to metal, if needed. The film is not needed if a non-stick mold coating is used or if a mold process is used that results in a non-stick interface. In the preferred embodiment, the shape of each indentation is substantially rectangular to achieve a planarized top surface of the first lenses. For purposes of easier release and to avoid any bright points, the edges of the substantially rectangular indentations are slightly rounded.

In FIG. 2, the mold indentions 18 have been filled (or partially filled to reduce waste) with a heat-curable liquid (or softened) lens material 20. The lens material 20 may be any suitable optically transparent material such as silicone, an epoxy, or a hybrid silicone/epoxy. A hybrid may be used to achieve a matching coefficient of thermal expansion (CTE). Silicone and epoxy have a sufficiently high index of refraction (greater than 1.4) to greatly improve the light extraction from an AlInGaN or AlInGaP LED. One type of suitable silicone has an index of refraction of 1.76. In the preferred embodiment, the lens material 20 is soft when cured to absorb differences in CTE between the LED dice 10 and the cured lens material 20.

In FIG. 3, the edges of the substrate wafer 12 are precisely aligned with the edges (or other reference points) on the mold 16. Note that the LED dice 10 are not precisely aligned with the indentations 18 in the x, y, and z directions due to the tolerances of the LED dice 10 mounting.

A vacuum seal is created between the periphery of the submount wafer 12 and the mold 16, and the two pieces are pressed against each other so that each LED die 10 is inserted into the liquid lens material 20, and the lens material 20 is under compression.

The mold 16 is then heated to about 150 degrees centigrade (or other suitable temperature) for a time to harden the lens material 20.

The submount wafer 12 is then separated from the mold 16, and the lens material 20 may be further cured by UV or heat to form a first clear lens 22 (FIG. 4) over each LED die 10. The lens 22 encapsulates the LED die 10 for protection and for heat removal and has outer dimensions precisely aligned with respect to the edges of the submount wafer 12 (or other reference points on the wafer 12). The first clear lens 22 has approximately the same shape as the LED die but slightly larger to cover the entire LED under worst case positioning of the LED die. Importantly, the outer “top” surfaces of all the first clear lenses 22 over the LED dice 10 are within the same planarized reference plane, since all the indentations 18 were identical.

In FIG. 4, in a second molding process identical to the first molding process, mold indentions 24 in a second mold 26 are filled (or partially filled to reduce waste) with a heat-curable liquid (or softened) lens material 28 containing phosphor powder. The lens material 28, other than the phosphor, may be similar to that used for the inner lens material 20 or may cure to form a harder lens. The phosphor may be a conventional YAG phosphor that emits a yellow-green light, or may be a red phosphor, a green phosphor, a combination of red and green phosphors, or any other phosphor, depending on the desired color of light to be produced. The blue light from the LED die 10 leaks through the phosphor to add a blue component to the overall light. The density of the phosphor and the thickness of the phosphor layer determine the overall color of the PC-LED. It is imperative for reproducible color from LED to LED that the phosphor layer thickness be always the same from one LED to the next at least across the top surface of the LED. Further, for uniformity of color over a wide range of viewing angles, the phosphor thickness should be uniform across the entire surface of each LED die, and substantially the same amount of LED light should illuminate all portions of the phosphor layer. Therefore, the shape of the phosphor layer should have approximately the same relative dimensions as the LED die 10, which is substantially rectangular.

As with the first molding process, the edges of the submount wafer 12 are precisely aligned with the edges (or other reference points) on the mold 26. Note that the first clear lenses 22 are now precisely aligned with the indentations 24 due to the indentations 18 and 24 being precisely aligned with respect to the molds' edges (or other reference points for alignment with the submount wafer 12).

A vacuum seal is created between the periphery of the submount wafer 12 and the mold 26, and the two pieces are pressed against each other so that each LED die 10 and first clear lens 22 are inserted into the liquid lens material 28, and the lens material 28 is under compression.

The mold 26 is then heated to about 150 degrees centigrade (or other suitable temperature) for a time to harden the lens material 28.

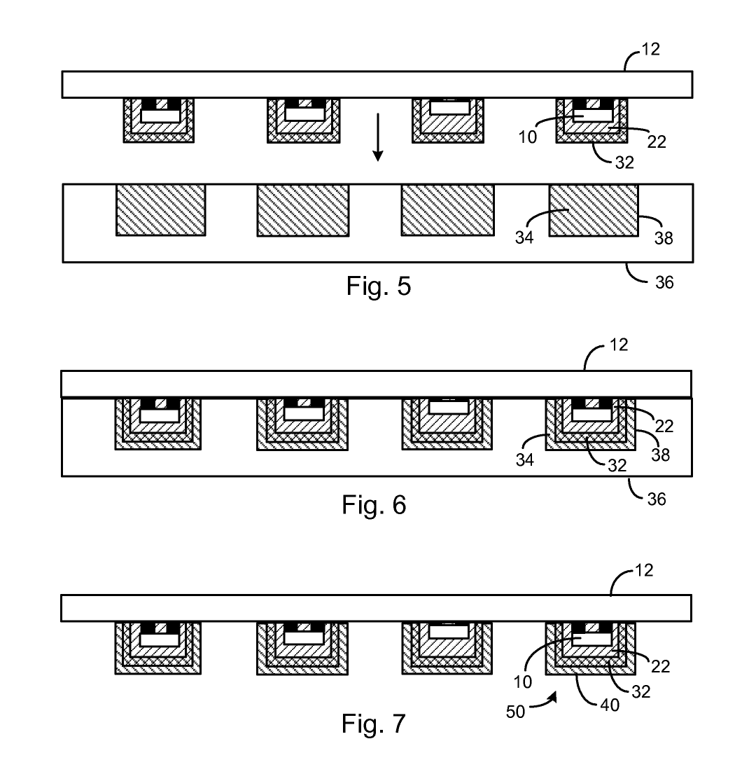

The submount wafer 12 is then separated from the mold 26, and the lens material 28 may be further cured by UV or heat to form a phosphor-infused second lens 32 (FIG. 5), having precise inner and outer dimensions, over each first clear lens 22. The inner dimensions are dictated by the first clear lens 22. The outer dimensions are dictated by the indentions 24, so the second lenses 32 all have identical thicknesses.

In FIGS. 5 and 6, a third molding step is performed identical to the previous molding steps, but the outer lens material 34 (e.g., a silicone) should have a lower index of refraction than the inner two lens materials to better couple light into the air (n=1). The third mold 36 indentations 38 are slightly larger than the indentations 24 of the second mold 26. The indentations 38 are filled with a clear liquid (or softened) lens material 34, and the submount wafer 12 and mold 36 are brought together under a vacuum. FIG. 6 shows the submount wafer 12 aligned with the third mold 36 so that the indentations 38 are aligned with both the inner clear lens 22 and the phosphor-infused second lens 32. The resulting outer lens 40 (FIG. 7) should be formed of a silicone that cures hard to provide protection and stay clean.

In one embodiment, the range of hardness of the first clear lens 22 is Shore 00 5-90, and the hardness of the clear outer lens 40 is greater than Shore A 30. The second lens 32 may be hard or have an intermediate hardness to absorb differences in CTE.

FIG. 7 shows the submount wafer 12 after separation from the mold 36 and after complete curing to create the hard outer lenses 40 for protection and improved light extraction from the PC-LEDs 50 The outer lens 40 may also contain molded features, such as roughening, prisms, or other features from indentations 38 that increase the extraction of light or diffuse the light for improved color and brightness uniformity across a wide viewing angle. The outer lens 40 may be any shape, such as rectangular, hemispherical, collimating, side-emitting, or other shape desired for a particular application.

The thickness of each of the first and second lens layers will typically be between 100-200 microns; however, in some instances the range may be 50-250 microns or thicker, depending on the amount of phosphor needed and other factors. The outer clear lens may have any thickness, such as from 50 microns to more than several millimeters, depending on its desired optical properties.

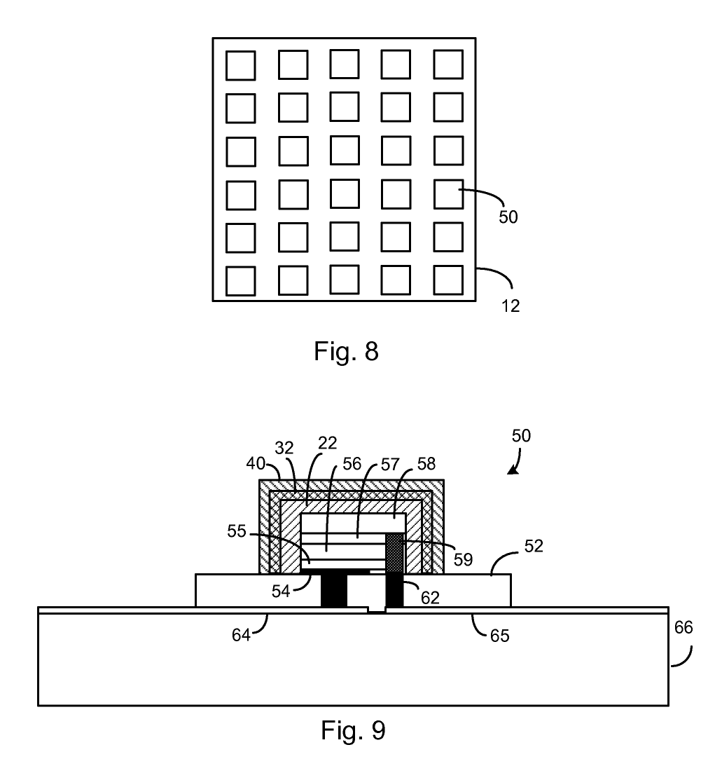

FIG. 8 is a front view of the submount wafer 12 with the completed, wafer-processed PC-LEDs 50 of FIG. 7. The submount wafer 12 is then diced to separate out the individual LEDs/submounts for mounting on a circuit board or for packaging.

FIG. 9 is a simplified close-up view of one embodiment of a single flip-chip PC-LED 50 on a submount 52, separated from the submount wafer 12 by sawing. The PC-LED 50 has a bottom p-metal contact 54, a p-contact layer 55, p-type layers 56, a light emitting active layer 57, n-type layers 58, and an n-metal contact 59 contacting the n-type layers 58. Metal pads on submount 52 are directly metal-bonded to contacts 54 and 59. Vias 62 through the submount 52 terminate in metal pads on the bottom surface of the submount 52, which are bonded to the metal leads 64 and 65 on a printed circuit board 66. The metal leads 64 and 65 are connected to other LEDs or to a power supply. Circuit board 66 may be a metal plate (e.g., aluminum) with the metal leads 64 and 65 overlying an insulating layer.

The inventive technique applies equally to PC-LEDs where most or virtually all LED light (e.g., blue or UV) is absorbed by the phosphor layer, and the resulting light is primarily the light emitted by the phosphor layer. Such a PC-LED would use a high density of phosphor in the phosphor layer. Such PC-LEDS may emit amber, red, green, or another color light other than white light.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A method for forming a phosphor-converted light emitting diode (PC-LED) comprising:
mounting a plurality of substantially rectangular LED dice on a submount wafer;
molding a substantially rectangular clear first lens directly over each of the LED dice by compression molding, wherein a first mold is first filled with a first lens material, then the LED dice are immersed into the first lens material under compression while the submount wafer is aligned with the first mold, thereafter the clear first lens material is cured, and the LED dice and clear first lenses are separated from the first mold, the clear first lenses encapsulating the LED dice;
molding a substantially rectangular second lens containing a phosphor directly over each of the clear first lenses by compression molding to substantially completely cover an outer surface of the clear first lenses, wherein a second mold is first filled with a second lens material containing the phosphor, then the LED dice and clear first lenses are immersed into the second lens material under compression, thereafter the second lens material is cured, and the LED dice, clear first lenses, and second lenses are separated from the second mold, the second lens having dimensions unrelated to any misalignments of the LED dice in x, y, and z directions on the submount wafer, top surfaces of all the second lenses being substantially in a single reference plane, and a thickness of the second lenses being substantially uniform;
molding a clear third lens directly over each of the second lenses by compression molding to substantially completely cover an outer surface of the second lenses, wherein a third mold is first filled with a third lens material, then the LED dice, clear first lenses, and second lenses are immersed into the third material under compression, thereafter the third lens material is cured, and the LED dice, clear first lenses, second lenses, and clear third lenses are separated from the third mold; and
separating the submount wafer to form individual PC-LEDs.

2. The method of claim 1 wherein the clear third lens is harder than the clear first lens.

3. The method of claim 1 wherein the clear third lens has an index of refraction lower than an index of refraction of the clear first lens.

4. The method of claim 1 wherein the submount wafer has metal leads in electrical contact with metal contacts on the LED dice.

5. The method of claim 1 wherein the clear third lens has molded features for affecting optical properties of the clear third lens.

6. The method of claim 1 wherein the clear first lens is substantially rectangular with rounded edges.

9. The method of claim 1 wherein a range of hardness of the clear first lens is Shore 00 5-90, and the hardness of the clear third lens is greater than Shore A 30.

10. The method of claim 1 wherein the LED dice emit visible blue light, and an overall color emitted by the PC-LED is a combination of the blue light and a light emitted by the phosphor in the second lens.

11. The method of claim 1 wherein the LED dice emit a first light color, and an overall color emitted by the PC-LED is primarily light emitted by the phosphor in the second lens.

12. The method of claim 1 wherein the second lens contains a plurality of phosphor types.

13. A phosphor-converted light emitting diode (PC-LED) formed by a method comprising:
mounting a plurality of substantially rectangular LED dice on a submount wafer;
molding a substantially rectangular clear first lens directly over each of the LED dice by compression molding, wherein a first mold is first filled with a first lens material, then the LED dice are immersed into the first lens material under compression while the submount wafer is aligned with the first mold, thereafter the clear first lens material is cured, and the LED dice and clear first lenses are separated from the first mold, the clear first lenses encapsulating the LED dice;
molding a substantially rectangular second lens containing a phosphor directly over each of the clear first lenses by compression molding to substantially completely cover an outer surface of the clear first lenses, wherein a second mold is first filled with a second lens material containing the phosphor, then the LED dice and clear first lenses are immersed into the second lens material under compression, thereafter the second lens material is cured, and the LED dice, clear first lenses, and second lenses are separated from the second mold, the second lens having dimensions unrelated to any misalignments of the LED dice in x, y, and z directions on the submount wafer, top surfaces of all the second lenses being substantially in a single reference plane, and a thickness of the second lenses being substantially uniform;
molding a clear third lens directly over each of the second lenses by compression molding to substantially completely cover an outer surface of the second lenses, wherein a third mold is first filled with a third lens material, then the LED dice, clear first lenses, and second lenses are immersed into the third material under compression, thereafter the third lens material is cured, and the LED dice, clear first lenses, second lenses, and clear third lenses are separated from the third mold; and
separating the submount wafer to form individual PC-LEDs.

14. The PC-LED of claim 13 wherein the clear third lens is harder than the clear first lens.

15. The PC-LED of claim 13 wherein the clear third lens has an index of refraction lower than an index of refraction of the clear first lens.

16. The PC-LED of claim 13 wherein the LED dice emit visible blue light, and an overall color emitted by the PC-LED is a combination of the blue light and a light emitted by the phosphor in the second lens.

17. An intermediate light emitting diode (LED) structure during manufacturing comprising:
a submount wafer, prior to dicing, having a plurality of substantially rectangular flip-chip LED dice mounted thereon,
each LED die having molded directly over it a substantially rectangular clear first lens, wherein each clear first lens is aligned with respect to the submount wafer rather than to the LED dice, such that misalignments of the LED dice on the submount do not affect positions of the clear first lens over each LED die,
each clear lens having molded directly over it a substantially rectangular second lens containing a phosphor to substantially completely cover an outer surface of each clear first lens, wherein each second lens is aligned with respect to the submount wafer rather than to the LED dice, whereby each second lens has dimensions unrelated to any misalignments of the LED dice in x, y, and z directions on the submount wafer, top surfaces of all the second lenses being substantially in a single reference plane, and a thickness of the second lenses being substantially uniform from LED die to LED die, and
each second lens having molded over it a clear third lens to substantially completely cover an outer surface of the second lens.
